(19) United States
(12) Patent Application Publication
(10) Pub. No.: US 2005/0266321 A1
(43) Pub. Date: Dec. 1, 2005

(54) Mask for proximity field optical exposure, exposure apparatus and method therefor

(75) Inventors: Isao Tsuruma, Ashigarakami-gun (JP); Masayuki Naya, Ashigarakami-gun (JP); Atsushi Mukai, Ashigarakmi-gun (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/144,944

(22) Filed: Jun. 6, 2005

Related U.S. Application Data
(62) Division of application No. 10/295,893, filed on Nov. 18, 2002, now abandoned.

(30) Foreign Application Priority Data
Nov. 19, 2001 (JP) P.2001-353377

(51) Int. Cl. G03F 1/00; G03B 27/58; G03B 27/42; G03C 5/00

(52) U.S. Cl. 430/5; 355/53; 355/72; 430/322

(57) ABSTRACT

A mask for exposure 1 having an aperture in a prescribed pattern formed on one surface and subjected to proximity field exposure in a state kept in contact with the surface of a wafer 2. The mask 1 is made of a transparent material such as glass or quartz glass. The mask 1 forms a circular shape with a thickness of 1 mm or less, preferably 0.1-0.5 mm.

### BACKGROUND OF THE INVENTION

1. Field of the Invention

This invention relates to a mask used for proximity field optical exposure for duplicating a fine pattern (hereinafter referred to as “mask”), and in an application technical field, relates to formation of a fine pattern which is applicable to a grating used as an optical circuit element such as a distributed feedback laser, for example, DFB and DBR.

2. Description of the Related Art

Development of optical lithography has been supported by the progress of a reduced projection exposure technique and a photoresist technique. The performance of the reduced projection exposure technique is mainly determined by two fundamental quantities of resolution RP and depth of focus DOP. Assuming that the exposure wavelength of a projection optical system is λ and the numerical aperture of a projection lens is N, the above fundamental quantities are represented as RP=k1λ/NA and DOP=k2λ/NA.

In order to improve the resolution of the lithography, it is important to decrease the wavelength λ and increase the numerical aperture NA of the projection lens.

In this case, if the NA is increased, the resolution is improved, whereas the depth of focus decreases in inverse proportion to the square of NA. The tendency of micromachining was to decrease the exposure wavelength λ. Therefore, the exposure wavelength λ has been shortened from g-line (436 nm) into a short wavelength of i-line (365 nm). At present, the main tendency is an excimer laser (248 nm, 193 nm).

However, in the lithography using light, the diffraction limit of light is the limit of the resolution. Therefore, it is said that even with the F2 excimer laser at 248 nm, the micromachining to the line width of 100 nm is the limit of the lithography using a lens series optical system. Further, in order to acquire the resolution in the order of magnitude of nanometer, the lithography of an electron beam or X-ray (particularly, SOR light: synchrotron radiation light) must be employed.

The electron beam lithography permits the pattern in the order of magnitude of nanometer to be controlled accurately, and provides much greater depth of focus than the optical system does. The electron beam lithography has an advantage that it can directly draw on a wafer without using a mask. However, the electron beam lithography has a defect that it provides a low throughput and requires high cost and has a long way to reach the level of mass production.

The X-ray lithography, in either equivalent exposure using a 1:1 mask or a reflective imaging X-ray optical system, permits the resolution and accuracy to be improved by one order of magnitude as compared with the exposure of excimer laser. However, the X-ray lithography is problematic in that it is difficult to implement because of difficulty of making the mask and provides high cost of the apparatus.

In the lithography using the electron beam or X-rays, the photoresist must be developed according to the exposure method. This lithography is still problematic from the viewpoints of sensitivity, resolution, etching resistance, etc.

As a method for solving these problems, there has been proposed a method of using, as a light source, proximity field light which oozes out from an aperture having a much smaller diameter than the wavelength of light to be projected and exposing photoresist to light and developing it to make a fine pattern.

This proposed method can provide the special resolution in the order of magnitude of nanometer regardless of the wavelength of a light source.

FIG. 12 is views showing the method of duplicating a fine pattern using proximity field exposure.

As seen from FIG. 12(a), photoresist of a photosensitive material is continuously applied to a substrate 31 by spin-coating or spraying to form a photoresist layer 33.

On the other hand, a mask 34 with a metallic minute pattern 36 on a mask substrate 35 of dielectric such as glass is prepared.

Next, as seen from FIG. 12(b), the mask 34 is brought into intimate contact with the photoresist layer 33 in such a way that the pattern 36 on the mask substrate 35 is opposite to the substrate 31.

As seen from FIG. 12(c), with the mask 34 superposed on the substrate 31, the rear surface of the mask substrate 35 is irradiated with the light 39 such as i-line (365 μm).

Then, as seen from FIG. 12(d), owing to the irradiation with the light of the i-line, proximity field light 37 oozes out from the aperture free from the metal of the pattern 36. Thus, exposure is made so that the corresponding portion h of the photoresist is exposed to light.

After optical exposure, as seen from FIG. 12(e), the mask 34 is taken from the substrate 31. The photoresist layer 33 is developed using a developing liquid. The portion h exposed to light is made soluble in a developing solvent, thereby forming a positive pattern.

Referring to a sectional view of an intimate-contact exposing apparatus using vacuum evacuation, an explanation will be given of a method of intimate-contact exposure. First, a wafer with the photoresist layer 33 applied on the substrate 31 is mounted on a stand of an exposure apparatus, and a mask 34 is mounted in contact with the wafer.

Before exposure, as seen from FIG. 13(a), an inert gas such as N₂ is continuously caused to flow between the mask 34 and the photoresist layer 33 within the apparatus. During the exposure, as seen from FIG. 13(b), the space between the mask 34 and the photoresist layer 33 is vacuum-exhausted so that the mask 34 is brought into contact with the photoresist layer 33. Thereafter, light 39 is projected from the rear surface of the mask.

As seen from FIG. 13(c), the N₂ gas is caused to flow within the apparatus again so that the mask 34 is separated from the photoresist layer.

Incidentally, in the above explanation, the photosensitive photoresist of the photoresist layer 33 was a positive pattern in which the exposed portion is soluble in a development solvent. However, it may be negative photoresist in which only the portion exposed to light is insoluble in the development solvent.

The thickness of the photoresist layer is desired to be equal to or smaller than the oozing depth of the proximity field light.

The photoresist material used in the photoresist layer 33 is preferably a material which can be developed in an aqueous alkaline development solution since it does not produce organic liquid wastes, provides less swelling and has high development capability to make a good pattern. More specifically, it may be pattern making material containing silicon-containing polymer which is water-insoluble and alkali-soluble and photosensitive compound.

In this way, the method of proximity field optical exposure through collective exposure using the mask has been proposed which has high industrial utility value from the standpoint of throughput. In this case, the proximity field light has small optical strength equal to an aperture width so that the mask must be in contact with the photoresist as intimate as possible.

A contact aligner which has been conventionally employed also effectively adopts a method of evacuating the space between the wafer and the mask in order to improve the pattern size accuracy so that they are brought into strong and intimate contact with each other.

However, in the above prior art, the exposure could be implemented in intimate contact between the wafer and mask by vacuum exhaustion. However, this enhanced intimate contact between the wafer and mask produces a problem of sticking that they cannot be separated.

### SUMMARY OF THE INVENTION

In order to solve the problem of sticking, a method of improving the resist material was attempted. However, this method produced a mask defect due to application of particles (dust). For this reason, in a conventional semiconductor process, projection exposure has been adopted. However, in the proximity field exposure in which propagating light can be employed, the mask and the resist face must be necessarily brought in intimate contact with each other. Therefore, the problem of sticking is a great obstacle in practical use.

In order to solve this problem, a technique has been proposed which makes a mask using flexible resin (PDMS: polydimethylsiloxane) as a mask material (J. VacSci. Technol. B1681. 1998). This technique has an advantage that the mask which is flexible and apt to deform can be easily peeled from the resist. On the other hand, since the mask is apt to deform, while the mask is made and during the exposure, the size of the mask pattern is likely to vary. This makes the pattern accuracy problematic. Particularly, the pattern employed for optical control such as a DBR grating, which requires high pitch controllability in the order of magnitude of nanometer, becomes problematic.

In the case of contact exposure, since the mask is repeatedly brought into intimate contact with the wafer, likelihood of application of particles on the mask is strong. This requires mask cleaning. However, since the mask which is made of resin is low in chemical/physical resistance, a conventional cleaning technique cannot be used.

Additionally, in order to avoid this problem, there has been proposed a technique in which inversely to the above proposal, the wafer is made as a membrene (thin film) to realize a pattern with minute pitches (Takahiko ONO and Masayoshi ESASHI, “Subwavelength Pattern Transfer by Proximity Field Photolithography” Jpn. J. Appln. Phys. Vol. 37(1998), pp. 6745-6749, Part 1, NO. 12B, December 1998).

However, this technique, which requires the wafer itself to be processed previously, is problematic in the freedom of selecting a material of wafer and the strength of the wafer and hence is not practical.

In order to attain the above object, the invention described in this invention is a mask for proximity field optical exposure wherein a light shading portion is formed so as to leave an aperture in a prescribed pattern on a surface of a mask body material that is transparent to exposure light, and the aperture as a patterning portion is subjected to proximity field optical exposure with being kept in contact with the surface of a wafer, said mask being made of a transparent material having a thickness of 1 mm or less.

Further, in this invention, a mask for proximity field optical exposure is provided, wherein said mask has a thickness of 0.1 mm-0.5 mm.

Further, in this invention, a mask for proximity field optical exposure is provided, wherein said mask forms a circular shape.

Still further, in this invention, an exposure apparatus is provided for performing proximity field optical exposure, comprising: a mask having a light shading portion formed to leave an aperture in a prescribed pattern on a surface of a mask body material that is transparent to exposure light, and the aperture as a patterning portion being kept in contact with the surface of a wafer; a wafer chuck for keeping a wafer opposed to the mask, and a pressure applying means for applying stress to deform said mask.

Further, in this invention, an exposure apparatus according to the above aspect, said pressure applying means applies stress to said mask by lifting said mask.

Further, in this invention, an exposure apparatus according to the above aspect, wherein said pressure applying means is provided with a gas blow-off means.

Further, in this invention, an exposure apparatus according to the above aspect, wherein said pressure applying means has a handler provided with a fork inserting portion to be inserted between said mask and a mask holding means for holding the mask.

Further, in this invention, an exposure apparatus according to the above aspect, wherein said mask is replaceable with another mask for each exposure time.

Still further, in this invention, said exposure apparatus includes a mask cleaning mechanism for cleaning the mask.

Further, in this invention, an exposure apparatus according to the above aspect, wherein said mask cleaning mechanism is implemented in oxygen plasma or ozone ashing.

Further, in this invention, said mask cleaning mechanism has scrubbers at both sides thereof respectively.

Further, in this invention, an exposure apparatus according to the above aspects, wherein said exposure apparatus includes an automatic inspection mechanism for automatically inspecting the cleaning state of said mask.

Still further, in this invention, a proximity field optical exposure method in which after a mask with a prescribed pattern is loaded on a mask chuck and a wafer with a photo-resist layer is loaded on a wafer chuck, said mask chuck and said wafer chuck are caused to approach each other so that the pattern of said mask is brought into intimate contact with said photoresist layer of said wafer in order to implement proximity field exposure, characterized in that after the exposure, a pressure applying means is caused to act on a peripheral edge of said mask so that said peripheral edge is elastically deformed, thereby starting peeling of the mask and wafer from each other.

### BRIEF DESCRIPTION OF THE DRAWINGS

FIGS. 1(a)-1(d) show the sectional views showing the thickness of a mask according to the first embodiment of this invention.

FIGS. 2(a) and 2(b) show the plan views showing the shapes of the mask shown in FIG. 1(a)-1(d).

FIG. 3 is a plan view of the wafer chuck shown in FIGS. 1(a)-1(d).

FIGS. 4(a) and 4(b) show the views each showing a mask lifting mechanism according to the second embodiment of this invention.

FIG. 5 is a view for explaining the peeling operation when compressed air is used in place of the lifting member shown in FIGS. 4(a) and 4(b).

FIGS. 6(a)-6(e) is the views showing the procedure of the peeling operation in an exposure sequence of the exposure apparatus shown in FIGS. 4(a) and 4(b).

FIGS. 7(a)-7(c) show the views showing the procedure of the peeling operation by gas jetting in the exposure apparatus shown in FIGS. 6(a)-6(e).

FIGS. 8(a)-8(d) show the views showing the peeling operation by a structure for the exposure sequence shown in FIGS. 6(a)-6(e).

FIG. 9 is a plan view of the structure shown in FIG. 8(a)-8(d).

FIG. 10 is a block diagram of the exposure apparatus having an automatic mask changer according to the third embodiment of this invention.

FIG. 11 is a block diagram of the exposure apparatus having a mask cleaning mechanism in place of the automatic mask changer shown in FIG. 10.

FIGS. 12(a)-12(e) show the view showing the technique of duplicating a minute pattern by proximity field exposure.

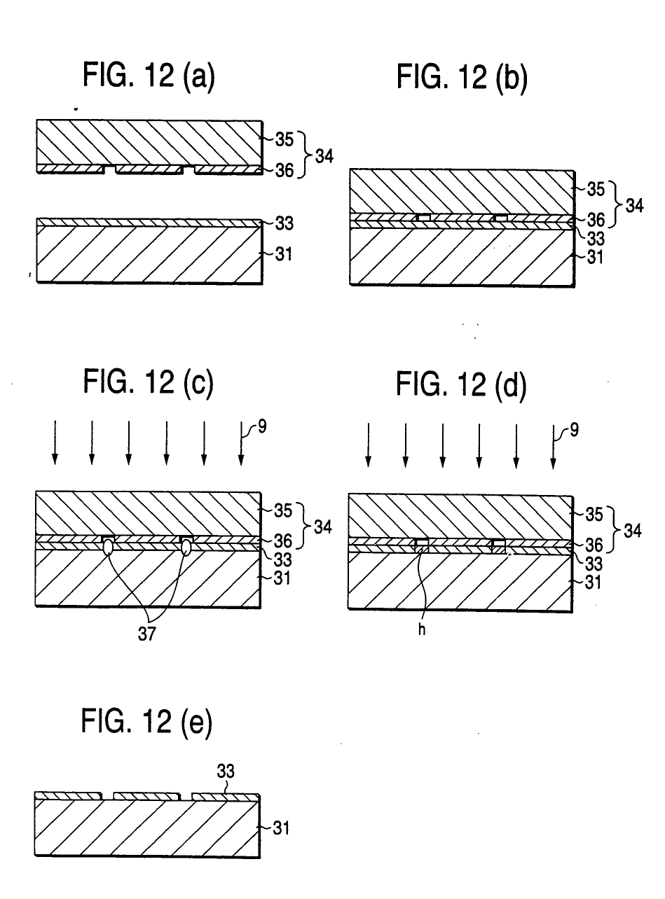

FIGS. 13(a)-13(c) show the sectional view of a contact exposure apparatus by vacuum evacuating.

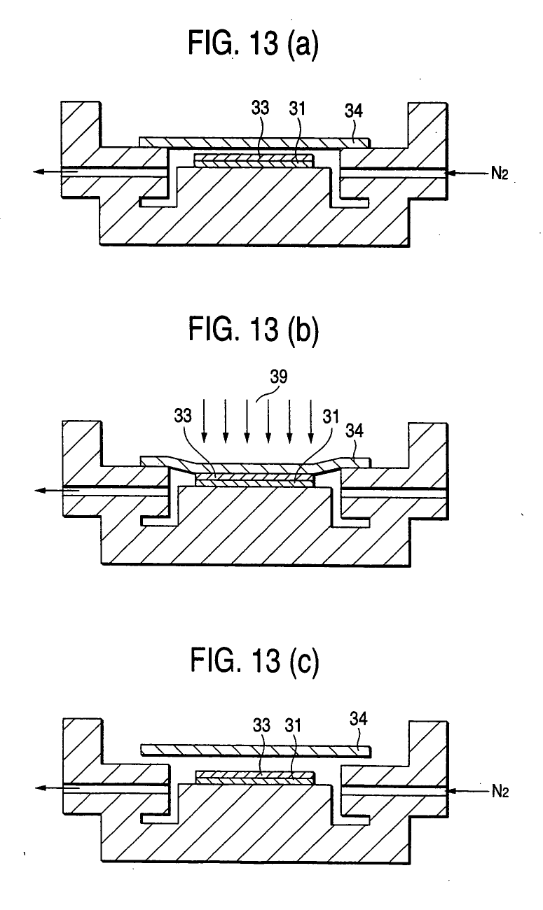

### DESCRIPTION OF THE PREFERRED EMBODIMENTS

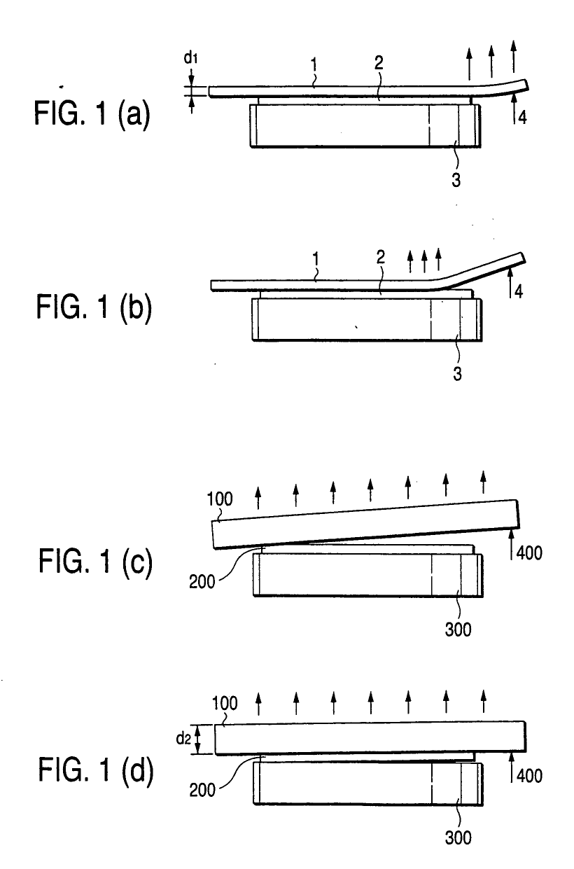

Now referring to FIGS. 1(a) to 11, an explanation will be given of this invention.

First, referring to FIGS. 1(a)-1(d), the first embodiment of this invention will be explained.

FIGS. 1(a)-1(d) show the views for explaining the relationship between the thickness of a mask and pressure. FIGS. 1(a) and 1(b) illustrate the case of the mask according to the first embodiment of this invention, and FIG. 1(c) and 1(d) illustrate the case of a conventional mask.

In FIGS. 1(c) and 1(d), reference numeral 100 denotes a conventional mask. The conventional mask 100, which is made of a material with high degree of transparency, has no need of being formed as thin as possible. Rather, in order to prevent the mask from being easily broken by faint force, it was formed to have a thickness d2 which is great as thick as 0.06 inch (1.5 mm) or more. Therefore, when stress 400 is applied to the end of the mask so that the mask is peeled from the water 200, the stress 400 is dispersed like in FIG. 1(c) since the mask has high rigidity, and hence must be very great.

Now, when the great stress 400 is applied, as seen in FIG. 1(d), an inconvenience occurred that the wafer 200 as well as the mask 100 is peeled from a vacuum chuck 300 before the mask 100 is peeled from the wafer 200.

The applicant defeated the traditional common sense and discovered that the mask having a thickness d1 which is as thin as possible can be peeled by faint force. Therefore, The applicant confirmed that owing to faint force applied to the mask, less breakage of the mask in the exposure step is generated.

FIGS. 1(a) and 1(b) show the mask according to the first embodiment of this invention. In FIGS. 1(a) and 1(b), reference numeral 1 denotes a mask in which a metallic light-shading film is formed on a substrate of glass or quartz/glass according to this invention. Reference numeral 2 denotes a wafer to be in intimate contact with the mask 1. Reference numeral 3 denotes a wafer chuck for holding the wafer 2. Reference numeral 4 denotes the stress by stress applying (peeling) means such as a pin for peeling the mask from the wafer 2.

The mask shown in FIGS. 1(a) and 1(b) are made of the material in which the metallic shading film is formed on the substrate of quartz/glass like the conventional mask. The mask according to this embodiment is characterized in that it has the thickness d1 of 1 mm or less, particularly 0.1-0.5 mm which is thinner than the conventional mask. The mask which was made thin in this way can be easily elastically deformed. Where the wafer 2 is peeled from the mask 1 after exposure, as seen in FIG. 1(a), when faint force 4 is applied to the end of the mask 1, the force is concentrated to that portion but not dispersed to the other portion. When the concentrated force exceeds the contact force with resist, that end will be peeled.

When the peeling at the end starts once, as seen in FIG. 1(b), the stress concentrated portion gradually shifts the contact area so that the entire area will be peeled eventually.

In this way, in accordance with the first embodiment of this invention, since the mask 1 made thin can be easily elastically deformed, the mask can be easily peeled from the resist by faint force. It was confirmed that the mask is not broken within the above range of the thickness, and confirmed that the mask is likely to be broken with a thickness d1 which is 0.1 mm or less.

Further, where particles exist on the wafer 2, the defective area can be reduced by the elastic deformation of the mask 1 made thin.

Further, since the transparent member is made of quartz/glass, its deformation to stress/heat can be reduced as compared with resin. This permits the pattern to be made with high accuracy.

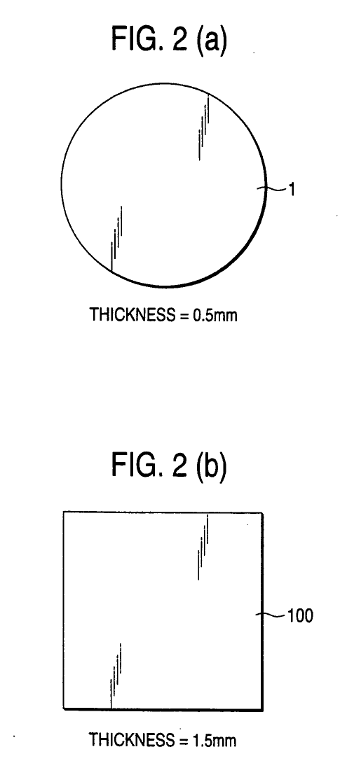

Referring to FIG. 2, the second embodiment of this invention will be explained below.

FIG. 2 is a plan view for explaining the shape of the mask.

FIG. 2(a) shows the mask according to the second embodiment of this invention. FIG. 2(b) shows a conventional mask.

As seen from FIG. 2(b), the conventional mask 100 forms a square shape. Where such a square mask 100 is peeled from the wafer 200 as shown in FIG. 1(b), with the stress 400 applied to the side area of the mask 100, this area is difficult to deform and hence to be peeled.

On the other hand, the mask 1 according to the second embodiment of this invention forms a circular shape. Therefore, the sectional secondary moment when stress is applied to the edge of the mask 1 can be reduced. In addition, any position on the entire periphery is easily elastically deformed by equal faint stress 4. The mask according to this embodiment can be more easily peeled from the wafer than the square mask.

A concrete example of the mask 1 will be explained.

First, quartz glass is molded into a wafer having a size of 4 inch φ which is thereafter polished to have a thickness of 0.5 mm. A Cr film having a thickness of 30 nm is deposited on the wafer by vacuum deposition. Further, by common electron beam lithography, the mask 1 with a minimum aperture having a width of 100 nm is manufactured.

Although depending on the means for applying the stress, where the compressed air (0.6 MPa) which is used as common pressurizing means is used, the thickness d1 of the mask 1 is preferably 1 mm or less to provide a deformation enough to peel. Where the mask is deformed with the pressure of 0.3 MPa or so which is convenient to use, with the thickness of 0.5 mm or less, improved peel could be realized. Inversely, where the mask is made thin to have a thickness of 0.1 mm or less, the strength is insufficient, thereby increasing the probability of breakage. This led to difficulty of handling such as polishing and cleaning in the manufacturing process described later.

Thus, it was confirmed that the mask thickness d1 of 0.1-0.5 mm is practically a range which permits the peeling and strength to be compatible.

Incidentally, in a step of applying resist on the wafer 2, photoresist is spin-coated on the wafer having a thickness of 0.4 mm and 3 inch φ. In this case, the resist applied film is caused to have a minimum aperture width of a mask slit or less. With the mask aperture width of 100 nm, the resist film after baking was caused to have a thickness of 50 nm. The mask pattern is brought into intimate contact with the photoresist layer of the wafer thus formed.

In such an intimate contact state, the rear side of the mask substrate is irradiated with the light of i-line. Owing to the light irradiation, the proximity field light oozed out from the pattern aperture of the mask so that the photoresist was exposed to light. After exposure, stress was applied to the side area of the mask to deform the mask that the mask was peeled from the wafer.

The wafer 2 thus peeled was subjected to prescribed steps of PEB, development and drying, thus forming a resist pattern. The resist pattern actually formed has a pattern width of about 15 nm.

Thus, by the proximity field optical lithography, the pattern whose width is larger than the aperture but sufficiently narrower than the exposure wavelength could be formed.

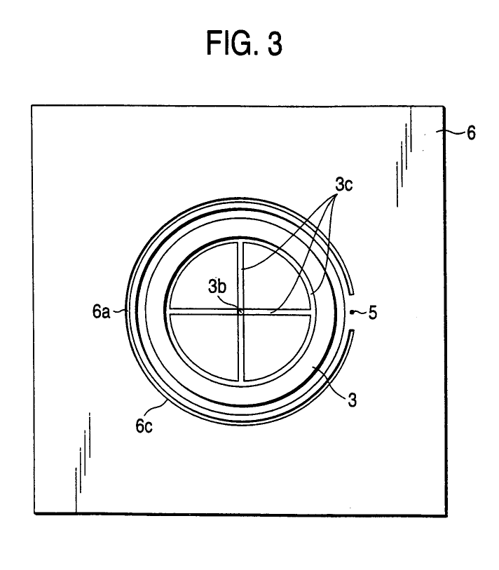

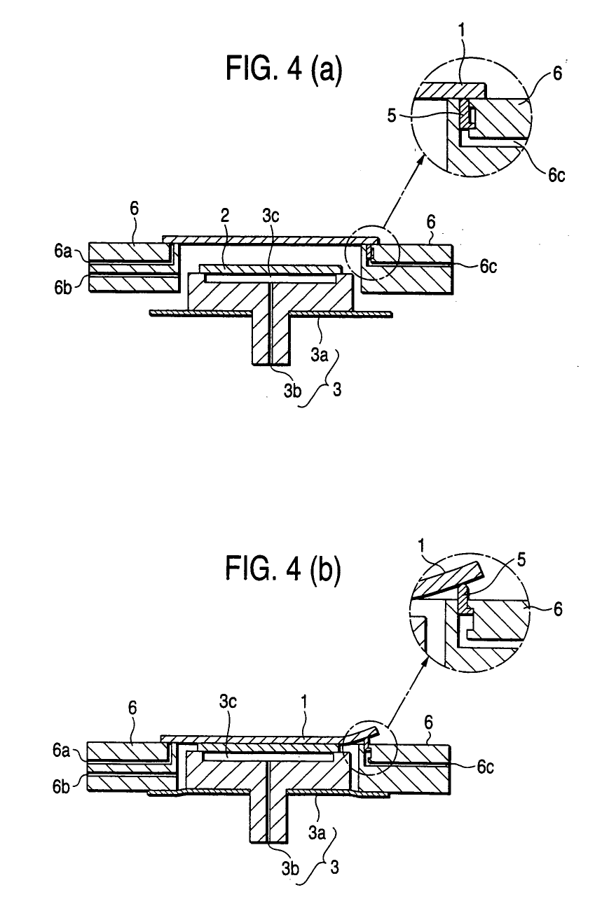

Referring to FIGS. 3 and 4, the third embodiment of this invention will be explained.

FIG. 3 is a plan view showing a mask lifting mechanism of the exposure apparatus according to the third embodiment of this invention. FIG. 4 is a front sectional view of the state where a mask and a wafer are loaded in the mask lifting mechanism of the exposure apparatus of FIG. 3.

In FIG. 3, reference numeral 3 denotes a wafer chuck; 3b an exhaust hole of the wafer chuck 3; 3c an exhaust groove; 6 a master chuck serving as a mask holding means; 6a a mask chuck exhaust hole; 6c a mask chuck exhaust groove; and 5 a lifting pin of a mask lifting member which is provided to be movable vertically with the mask chuck exhaust hole 6a. The lifting pin 5 ascends when compressed air is supplied and descends when it is exhausted.

In FIG. 4, the other components of the mask lifting mechanism are as follows. Reference numeral 1 denotes a mask loaded on the mask chuck 6; 2 a wafer loaded on the wafer chuck 3; 6b an mask/wafer exhaust hole; and 6c an air supplying hole for driving the lifting pin 5.

An explanation will be given of the operation of the mask lifting mechanism of FIGS. 3 and 4.

As described above, the thin circular mask 1 which is apt to deform elastically according to the first and the second embodiment of this invention is placed on the mask chuck 6 shown in FIGS. 3 and 4. By exhaustion from the mask exhaust hole 6a, the mask 1 is firmly loaded on the mask chuck 6. On the other hand, the wafer 2 which is to be irradiated with proximity field light is placed on the wafer chuck 3. By exhaustion from the wafer chuck exhaust hole 3b, the wafer 2 is sucked by the wafer chuck exhaust groove 3c so that it is firmly loaded on the wafer chuck 3. At the time of loading, as seen from FIG. 4(a), the mask chuck 6 and wafer chuck 3 are located apart from each other. During the exposure, the mask chuck 6 and the wafer chuck 3 are kept in contact with each other.

After the exposure, as seen from FIG. 4(b), compressed air is supplied into the air supplying hole 6c for driving the lifting pin 5. Thus, the lifting pin 5 is lifted upward so that the edge area of the deformable mask 1 according to the first and the second embodiment is lifted so as to deform. In this way, the mask 1 can be peeled from the wafer 2 easily and surely.

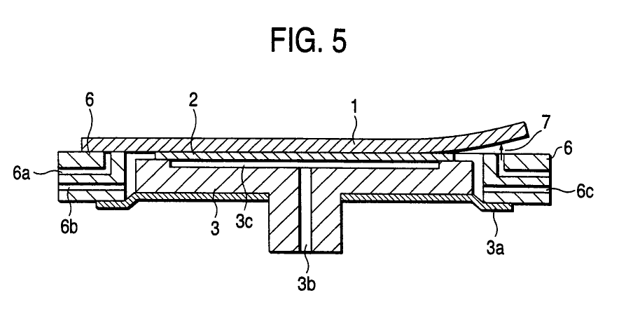

FIG. 5 shows an modification of the mask lifting mechanism of FIG. 4 in which compressed air is used in place of the lifting pin 5. In FIG. 5, reference numeral 1 denotes a mask loaded on the mask chuck 6; 2 a wafer loaded on the wafer chuck 3; 6b a mask/wafer exhaust hole; 3 a wafer chuck; 3a a seal of the wafer chuck 3; 3b an exhaust hole of the wafer chuck 3; 3c an exhaust groove of the wafer chuck 3; 6 a mask chuck serving as a mask holding means; 6a a mask chuck exhaust hole; 6b a mask/wafer exhaust hole; 6c a compressed air supplying hole; 7 a compressed air for lifting exhausted from the compressed air supplying hole 6c. In peeling, as seen from FIG. 5, the compressed air (or N₂ gas) is sprayed between the wafer 2 and mask 1 so that the pressure thus generated peels the mask 1 and the wafer 2 from each other.

The mask lifting mechanism shown in FIG. 5, which does not require that the lifting pin 5 and its attaching space as shown in FIG. 4 are machined, is convenient.

Referring to the drawings, an explanation will be given of the exposure sequence of the exposure apparatus according to this invention.

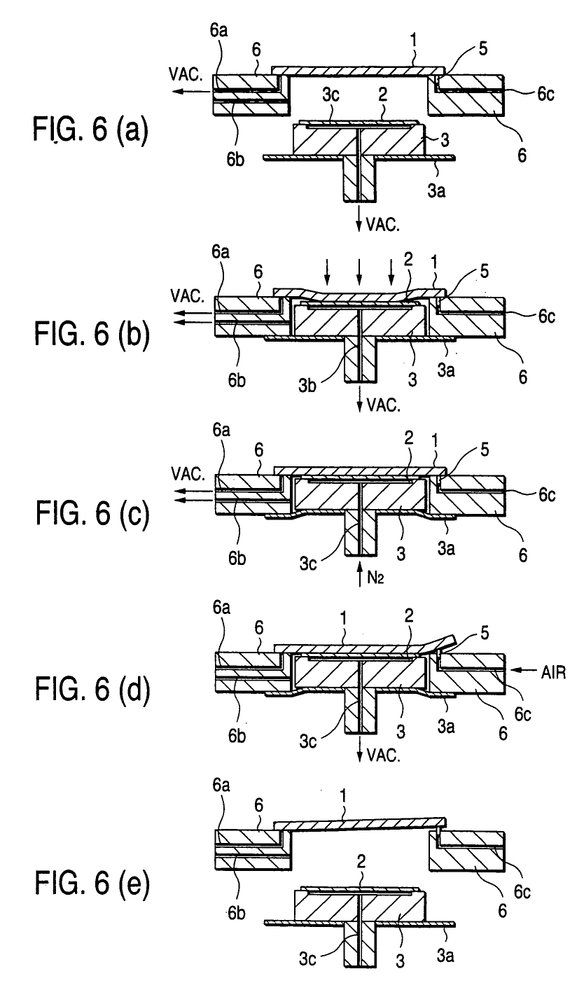

First, as shown in FIG. 6(a), with the resist applied Si wafer 2 having a thickness and shape according to this invention set in the wafer chuck 3, when air exhaustion is effected from the wafer chuck exhaust hole 3b, the entire bottom of the wafer 2 is secured on the wafer chuck 3 by vacuum chucking through the exhaust groove 3c shown in FIG. 3. On the other hand, with the mask 1 set in the mask chuck 6, when the air exhaustion is effected from the mask chuck exhaust hole 6a, the mask 1 is also secured by vacuum chucking.

Next, as seen from FIG. 6(b), with the wafer 2 and mask 1 aligned with each other by alignment means (manipulator), while the space between the mask 1 and wafer 2 is decompressed from the wafer/mask exhaust hole 6b, the wafer chuck 3 is raised (or the mask chuck 6 is lowered) so that the mask 1 and wafer 2 are caused to approach each other and brought into contact with each other.

In this case, by decompression, the wafer chuck seal 3a is brought into contact with the bottom of the mask chuck 6 so that it is deformed convexly upward (toward the wafer side) and the mask 1 is deformed convexly downward (toward the wafer side). Thus, the remaining gas is expelled from the center of the wafer so that the degree of contact between the wafer and mask is improved (This effect is remarkable as the thickness of the mask decreases to increase the deformation).

Thereafter, as seen from FIG. 6(c), before complete contact, the vacuum exhaust by the wafer chucking is released or the pressurizing is done using N₂ gas, poor contact which is attributable to the sinking of the wafer in the chuck groove during the wafer chucking is reduced.

Finally, the surface of the wafer 2 is raised to be flush with the lower surface of the mask 1. After the mask 1 is made horizontal, the wafer 2 is secured on the mask 1.

Upon completion of setting which is ready for exposure, by a proximity field optical exposure system using a high pressure mercury lamp (g, h, i lines), ultraviolet rays are applied during a prescribed time. In this case, the applying direction is adjusted to provide polarized light in parallel to the slit direction of the mask 1.

Upon completion of the exposure, the wafer chuck 3 which has been once released is decompressed again to effect the vacuum chucking. The decompressed wafer/mask exhaust hole 6b is released and the mask chuck exhaust hole 6a is also released so that they are restored to atmospheric pressure. In this state, as seen from FIG. 6(d), the end area of the mask 1 is lifted by the mask lifting pin 5 to peel the end of the wafer from the mask 1. Further, as shown in FIG. 6(e), the wafer chuck 3 is lowered so that the entire wafer 2 can be peeled from the mask 1.

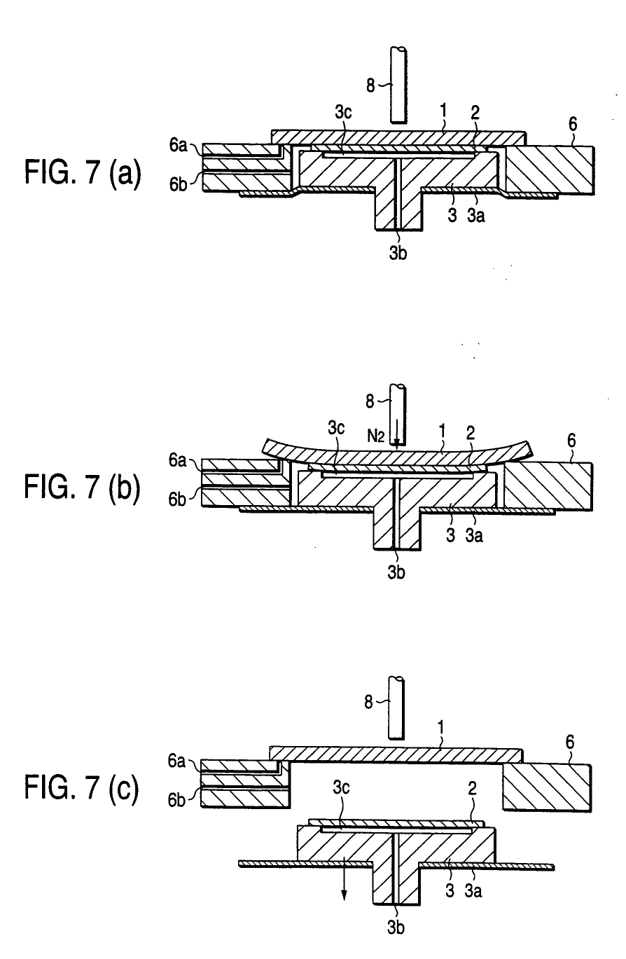

FIG. 7 is a view for explaining the mask peeling mechanism according to the fourth embodiment of this invention.

In FIG. 7, reference numeral 1 denotes a mask loaded on the mask chuck 6; 2 a wafer loaded on the wafer chuck 3; 6b a mask/wafer exhaust hole; 3 a wafer chuck; 3a a seal of the wafer chuck 3; 3b an exhaust hole of the wafer chuck 3; 3c an exhaust groove of the wafer chuck 3; 6 a mask chuck serving as a mask holding means; 6a a mask chuck exhaust hole; 6b a mask/wafer exhaust hole; and 8 a gas blow-off tube. The other components than the gas blow-off tube 8 have the same functions as those of the corresponding components in the above mask peeling mechanism.

An explanation will be given of the operation of the mask peeling mechanism according to this embodiment of this invention.

FIG. 7(a) shows the state after the exposure has been completed. In FIG. 7(a), after the exposure, the gas blow-off tube is arranged at the center of the mask 1.

Thereafter, as seen from FIG. 7(b), while the wafer chuck 3 is lowered, the N₂ gas (which may be replaced by compressed gas) is jet toward the top of the mask 1 from the gas blow-off tube 8. Thus, the central portion of the deformable mask 1 according to this invention is deformed downward so that a gap is produced between the mask 1 and wafer 2. At the same time, if the air is supplied into the wafer chuck exhaust hole 3b and mask/wafer exhaust hole 6b, the peeling can be effected more surely.

Further, when the wafer chuck 3 is lowered, as seen from FIG. 7c, the wafer 2 and the mask 1 can be peeled from each other.

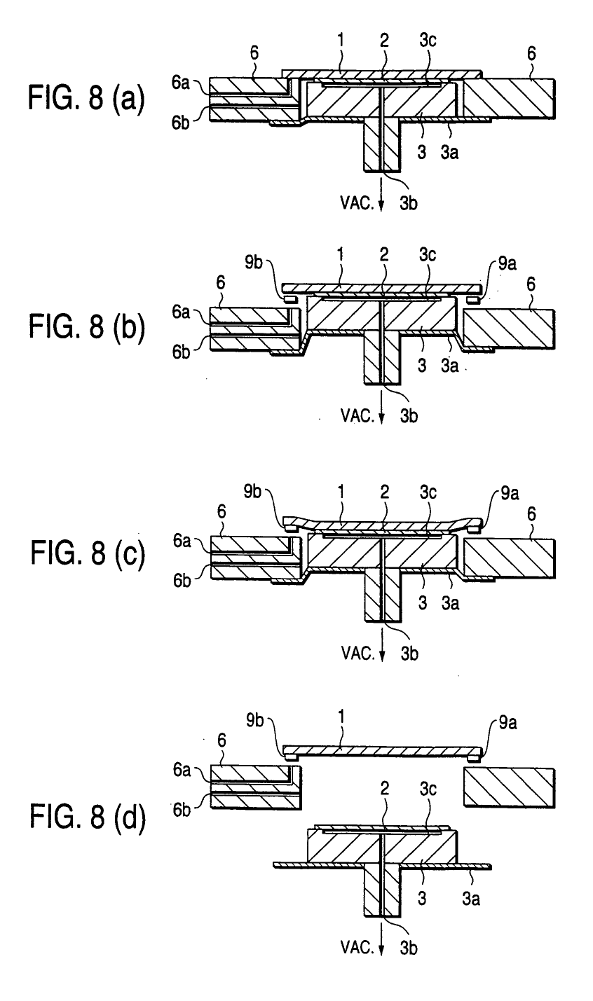

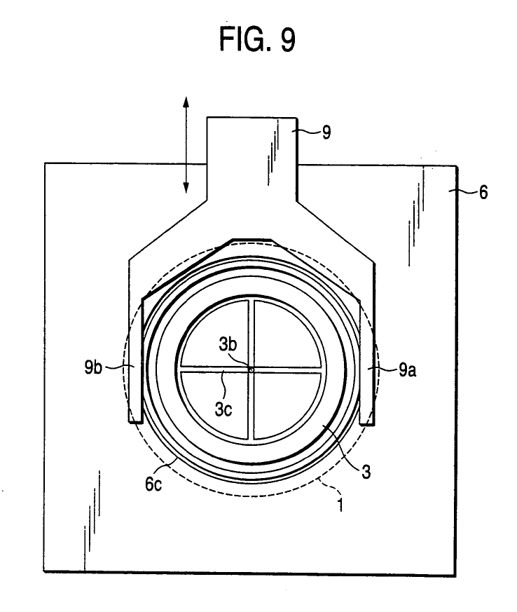

FIG. 8 is a view for explaining the peeling procedure according to the fifth embodiment of this invention in which a handler 9 as shown in FIG. 9 is employed. In FIG. 8, reference numeral 1 denotes a mask loaded on the mask chuck 6; 2 a wafer loaded on the wafer chuck 3; 3b a mask/wafer exhaust hole; 3 a wafer chuck; 3a a seal of the wafer chuck 3; 3b an exhaust hole of the wafer chuck 3; 3c an exhaust groove of the wafer chuck 3; 6 a mask chuck serving as a mask holding means; 6a a mask chuck exhaust hole; 6b a mask/wafer exhaust hole; and 9 a handler. The other components than the handler 9 have the same functions as those of the corresponding components in the above mask peeling mechanism. The structure of the handler 9 is shown in a plan view of FIG. 9.

In FIG. 9, reference numeral 3 denotes a wafer chuck; 3a a seal of the wafer chuck 3; 3b an exhaust hole of the wafer chuck 3; 3c an exhaust groove of the wafer chuck 3; 6 a mask chuck serving as a mask holding means; 6a a mask chuck exhaust hole; 6b a mask/wafer exhaust hole; and 9 a handler. A mask 1 is indicated by dotted line. The handler 9 includes tips 9a and 9b (hereinafter referred to as a tuning fork inserting portions) brunched in parallel from the base of the handler toward the tip. The interval between the tuning fork inserting portions 9a and 9b is slightly larger than the outer diameter of the wafer chuck 3 and slightly smaller than the outer diameter of the circular mask according to this invention. Further, the depth of the space formed by the tuning fork inserting portions 9a and 9b is larger than the radius of the wafer chuck 3.

Referring to FIG. 8 again, an explanation will be given of the procedure of the peeling operation using the handler 9 shown in FIG. 9.

FIG. 8 shows the state where the exposure has been completed.

Upon completion of the exposure, as shown in FIG. 8(b), the wafer chuck 3 is raised upward from the sucking plane of the mask chuck 6. Further, the fork inserting portions 9a and 9b of the handler 9 shown in FIG. 9 are inserted in the gap between the mask 1 and mask chuck 6.

Thereafter, when the wafer chuck 3 is lowered and the mask 1 is pressed against the handler 9, as shown in FIG. 8(c), the mask 1 start to deform.

When the wafer chuck 3 continues to be lowered as it is, the mask 1 and the wafer 2 are eventually peeled from each other as shown in FIG. 8(d).

In this case, after the end of the wafer starts to be peeled, if the N₂ gas is blown into the gap between the wafer 2 and the mask 1, the peeling can be made more easily.

An explanation will be given of the sixth embodiment of this invention.

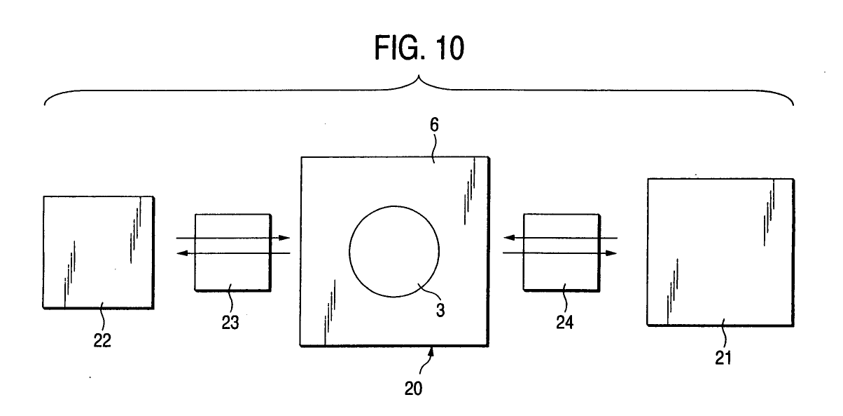

FIG. 10 is a block diagram of the exposure apparatus having an automatic mask changer according to the sixth embodiment of this invention.

In a conventional exposure apparatus, a single mask was set in the mask chuck to process a plurality of wafers successively. However, in the proximity field lithography, since the exposure is made with the wafer 2 and the mask 1 being in contact with each other, the particles such as resist were applied to the mask. This led to deterioration of the contact and occurrence of pattern defects, thereby making it difficult to put the proximity field lithography into practice. In order to overcome such difficulty, in the sixth embodiment of this invention, the same number of masks 1 as the wafers 2 are prepared so that the mask 1 is automatically replaced by another mask whenever the single wafer is exposed.

In the automatic mask changer shown in FIG. 10, reference numeral 20 denotes an exposure unit which incorporates the exposure mechanism or peeling mechanism shown in FIGS. 3 to 9. Reference numeral 21 denotes a mask carrier which holds a plurality of masks as shown in FIGS. 1 and 2. Reference numeral 22 denotes a wafer carrier which holds a plurality of wafers 2. Reference numeral 23 denotes a wafer transporting system or a transporting robot which transports the wafer 2 from the wafer carrier 21 to the exposure unit 20 so that it is set in the wafer chuck 3 and after exposure, takes it out. Reference numeral 24 denotes a mask transporting system or transporting robot which sets the mask 1 on the mask carrier 21 in the mask chuck 6 and after exposure, takes it out.

An explanation will be given of the operation of the exposure apparatus having an automatic mask changer according to the sixth embodiment of this invention shown in FIG. 10.

Using the manipulator of the wafer transporting system 23, the wafer 2 on the wafer carrier 22 is caught and set on the wafer chuck 3 of the exposure unit 20. Next, using the manipulator of the mask transporting system 24, the mask 2 in the mask carrier 21 is set on the wafer chuck 3 of the exposure unit 20.

The subsequent operation will be carried. For example, as seen from FIGS. 6(a) to (c), the mask 1 and wafer 2 are aligned with each other, brought into intimate contact with each other and secured in the exposure unit 20.

Upon completion of the exposure, the mask 1 and the wafer 2 are peeled from each other in the manner shown in FIGS. 6(d) to (e) and the peeling means as shown in FIGS. 7 to 9.

Upon completion of the peeling, for example, the wafer 2 is taken out from the exposure unit 20 to the next step through the wafer transporting system 23. Otherwise, it is returned to the wafer carrier 22 as the processed wafer to be stored. In this case, the second wafer 2 is transported from the wafer carrier 22 and set on the wafer chuck 3 (Incidentally it should be noted that the order of these operation should not be limited).

Subsequently, the mask 1 is carried out from the exposure unit 20 through the mask transporting system 24 and returned to the mask carrier 21 the used mask to be stored. In this case, the second mask 1 is transported to the exposure unit 20 and set on the mask chuck 6. This is succeeded by the processing shown in FIG. 6 et seq.

In this case, since the mask 1 to be used forms the same circular shape as the common wafer 1, it can be employed without greatly changing the conventional wafer transporting mechanism. This gives an advantage of reducing the apparatus cost.

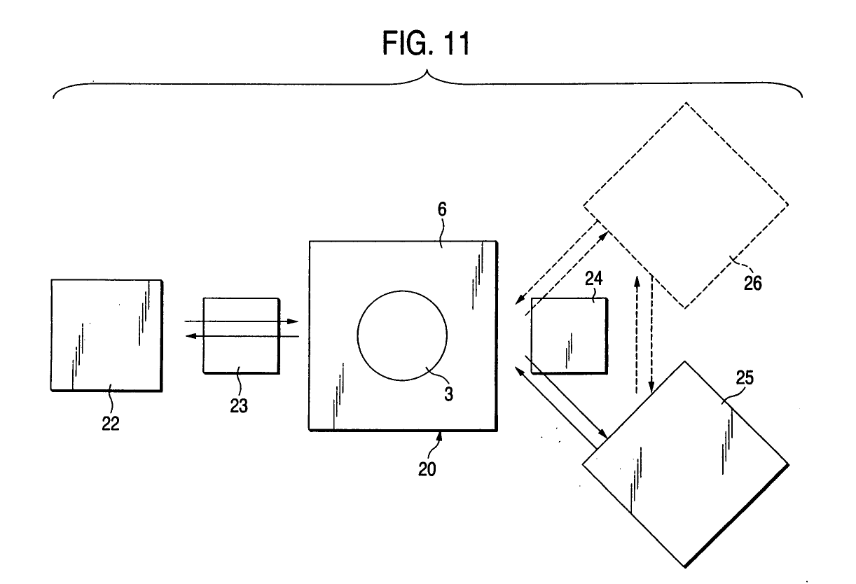

FIG. 11 shows an exposure apparatus provided with a mask cleaning mechanism 25 in place of the automatic mask changer shown in FIG. 10. This embodiment permits the mask to be not changed but cleaned, and to be used for a plurality of wafers.

In FIG. 11, reference numeral 25 denotes a mask cleaning mechanism which may be actually a plasma or ozone ashing apparatus, or scrubber apparatus for carrying out both-side blushing.

Reference numeral 26 denotes an inspecting unit for inspecting particles to confirm the cleaning state of the mask 1. As the case may be, this inspecting unit may be combined with the mask cleaning mechanism 25.

An explanation will be given of the exposure apparatus according to this embodiment shown in FIG. 11.

By the wafer transporting system 23 and the mask transporting system 24, the wafer 2 and the mask 1 are set on the wafer chuck 3 and mask chuck 6, respectively, and in this state, the exposure is carried out.

Upon completion of the exposure, the wafer 2 is carried out through the wafer transporting system 23 and the second wafer is set on the wafer chuck 3.

The mask 1 is transported to the mask cleaning mechanism 25 through the mask transporting system 24 and subjected to a cleaning step. Thereafter, the mask 1 is transported to the inspecting unit 26 through the mask transporting system 24. The mask 1 is subjected to a particle inspecting step by optical inspection by the inspecting unit 26. If the inspection result is OK, the mask 1 is transported to the exposure unit 20 through the mask transporting system 24, and set on the mask chuck 6 again.

If the inspection result is not OK, the mask 1 is returned to the mask cleaning mechanism 25. The mask 1 is cleaned again and transported to the inspecting step.

In this case, as the mask cleaning mechanism, the apparatus which has been employed as a conventional wafer process can be used. This contributes to cost reduction.

The exposure apparatus has been explained hither to assuming that the mask 1 having a thickness of 0.1-0.5 mm and forming a circular shape according to this invention is used. However, using an ordinary mask, the proximity field lithography can be carried out to provide high production yield. Therefore, the proximity field lithograph should not be limited to the case where the mask forming the circular shape according to this invention is used.

As understood from the description hitherto made, in accordance with this invention, by reducing the thickness of the mask, the exposure process which is good in the contact between the wafer and the mask and the peeling from each other can be realized without greatly changing the shape of the substrate.

Further, by reducing the thickness of the mask, also where there are particles on the wafer, a defective area can be reduced by the deformation of the mask.

By making the mask in the same circular shape as the wafer, the mask can be easily deformed at the periphery of the wafer in contact with the mask, and hence the mask can be easily peeled from the wafer.

Further, by making the mask in the circular shape, a conventional wafer process apparatus can be employed in the process of making the mask. This contributes to the cost reduction.

Further, by making the mask in the circular shape, the wafer and mask can be easily peeled from each in a manner of applying stress to the mask using the lifting pin or compressed air. This solves the problem of sticking.

Further, by providing the exposure with the automatic mask changer or cleaning machine, reduction in the production yield due to mask contamination by the contact exposure can be avoided.

1-3. (canceled)

4. An exposure apparatus for performing proximity field optical exposure, comprising:
a mask having a light shading portion formed to leave an aperture in a prescribed pattern on a surface of a mask body material that is transparent to exposure light, and the aperture as a patterning portion being kept in contact with the surface of a wafer,
a wafer chuck for keeping a wafer opposed to the mask, and
a pressure applying means for applying stress to deform said mask.

5. An exposure apparatus according to claim 4, wherein said pressure applying means applies stress to said mask by lifting said mask.

6. An exposure apparatus according to claim 4, wherein said pressure applying means is provided with a gas blow-off means.

7. An exposure apparatus according to claim 4, wherein said pressure applying means has a handler provided with a fork inserting portion to be inserted between said mask and a mask holding means for holding the mask.

8. An exposure apparatus according to claim 4, wherein said mask is replaceable with another mask for each exposure time.

9. An exposure apparatus according to claim 4, wherein said exposure apparatus includes a mask cleaning mechanism for cleaning the mask.

10. An exposure apparatus according to claim 9, wherein said mask cleaning mechanism is implemented in oxygen plasma or ozone ashing.

11. An exposure apparatus according to claim 9, wherein said mask cleaning mechanism has scrubbers at both sides thereof respectively.

12. An exposure apparatus according to any one of claims 9 to 11, wherein said exposure apparatus includes an automatic inspection mechanism for automatically inspecting the cleaning state of said mask.

13-15. (canceled)
